(19) United States
(12) Patent Application Publication
(10) Pub. No.: US 2013/0346813 A1
(43) Pub. Date: Dec. 26, 2013

(54) MEMORY TESTING SUPPORT METHOD AND MEMORY TESTING SUPPORT APPARATUS

(71) Applicant: FUJITSU LIMITED, KANAGAWA (JP)

(72) Inventor: Tamoru INOUE, Kawasaki (JP)

(73) Assignee: FUJITSU LIMITED, KANAGAWA (JP)

(21) Appl. No.: 14/010,951

(22) Filed: Aug. 27, 2013

Related U.S. Application Data
(63) Continuation of application No. PCT/JP2011/056458, filed on Mar. 17, 2011.

(51) Int. Cl. G11C 29/10

(52) U.S. Cl. CPC G11C 29/10
USPC 714/719

(57) ABSTRACT

A memory testing support method includes executing a procedure using a plurality of test patterns on a memory to be tested; recording an observation result of a current value flowing in the memory during the execution of the procedure using each of the test patterns into a storing section; and determining superiority or inferiority of the test patterns in terms of effectiveness of testing the memory based on the observation results of the test patterns recorded in the storing section.

### CROSS-REFERENCE TO RELATED APPLICATIONS

This application is a continuation application of International Application PCT/JP2011/056458 filed on Mar. 17, 2011 and designated the U.S., the entire contents of which are incorporated herein by reference.

### FIELD

The disclosures herein relate to a memory testing support method and a memory testing support apparatus.

### BACKGROUND

For testing a memory such as a DIMM (Dual In-line Memory Module) or a SIMM (Single In-line Memory Module), a program (called a “memory testing program”) is used. A memory testing program executes write and read on a memory based on a test pattern that includes, for example, an access pattern on the memory and a data pattern written into the memory, and detects a fault in the memory if any exists.

Fault detection capability of a test pattern depends on system architecture of a device to be tested and the type of a memory to be tested. Therefore, conventionally, multiple test patterns different from each other are provided for testing a certain type of memory, and effective test patterns for the memory are selected among the provided patterns. Specifically, the provided test patterns are run on the memory, and a test pattern with a high fault detection rate is selected as the test pattern to be used for the memory.

However, as there are no all-round test programs suitable for all types of memories, an effective test pattern needs to be selected every time when a new memory is developed. Alternatively, a new test pattern may be developed focusing on characteristics of the new memory.

### RELATED-ART DOCUMENTS

### Patent Documents

[Patent Document 1] Japanese Laid-open Patent Publication No. 11-7795
[Patent Document 2] Japanese Laid-open Patent Publication No. 2001-21623
[Patent Document 3] Japanese Laid-open Patent Publication No. 6-313791

However, conventionally, effectiveness of a test pattern is determined based on whether a fault in a memory is detected when running the test pattern on the memory to be tested. This means that it is necessary to search for a fault in a memory before searching for effective test patterns for the memory to be tested, and in addition to that, it is necessary to confirm whether the fault can be detected by each of the search-detected test patterns. Therefore, there has been a problem in that it takes a very long time to select effective test patterns for a memory to be tested.

### SUMMARY

According to an embodiment of the present invention, a memory testing support method includes: executing a procedure using a plurality of test patterns on a memory to be tested; recording an observation result of a current value flowing in the memory during the execution of the procedure using each of the test patterns into a storing section; and determining superiority or inferiority of the test patterns in terms of effectiveness of testing the memory based on the observation results of the test patterns recorded in the storing section.

The object and advantages of the embodiment will be realized and attained by means of the elements and combinations particularly pointed out in the claims. It is to be understood that both the foregoing general description and the following detailed description are exemplary and explanatory and are not restrictive of the invention as claimed.

### BRIEF DESCRIPTION OF DRAWINGS

FIG. 1 is a schematic view illustrating a hardware configuration example of a system board of a memory testing support apparatus according to an embodiment of the present invention;

FIG. 2 is a schematic view illustrating a functional configuration example of a memory testing support apparatus according to an embodiment of the present invention;

FIG. 3 is a schematic view illustrating a relationship between a testing task and a measurement task;

FIG. 4 is a flowchart illustrating an example of processing steps in a memory testing support apparatus;

FIG. 5 is an example of a timing chart for a testing task and a measurement task; and

FIG. 6 is a schematic view illustrating a configuration example of an observation result storing unit.

### DESCRIPTION OF EMBODIMENTS

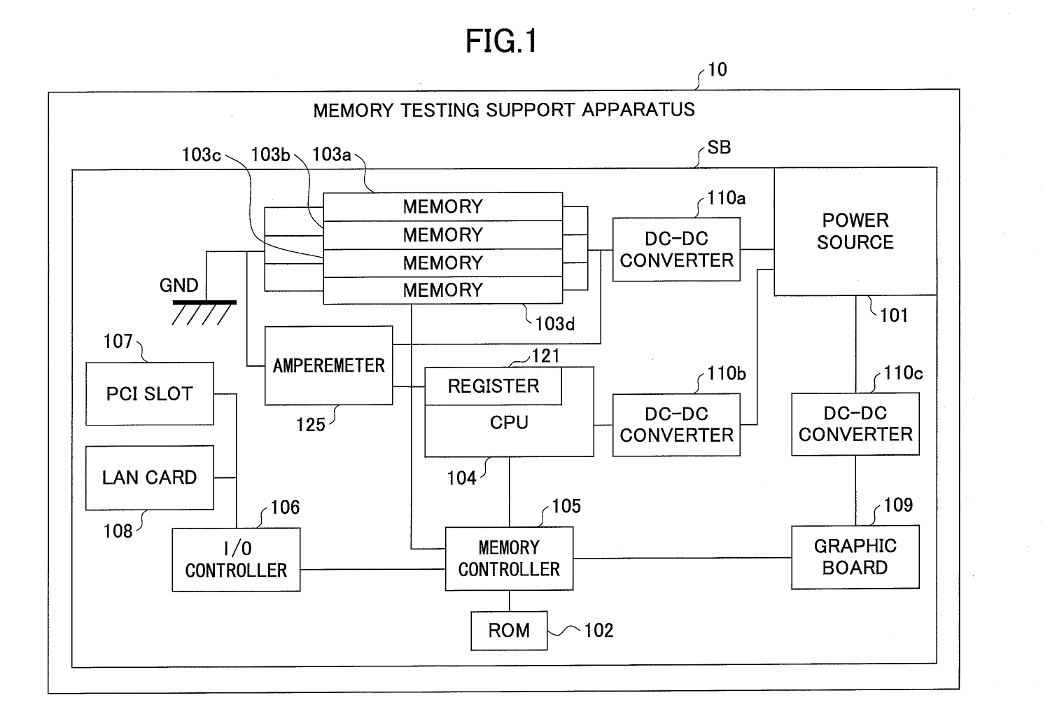

In the following, embodiments of the present invention will be described with reference to the drawings. FIG. 1 is a schematic view illustrating a hardware configuration example of a system board of a memory testing support apparatus 10 according to an embodiment of the present invention. In FIG. 1, a system board SB of the memory testing support apparatus 10 includes a power source 101, a ROM 102, memories 103a-d, a CPU 104, a memory controller 105, an I/O controller 106, a PCI slot 107, a LAN (Local Area Network) card 108, a graphic board 109, DC-DC converters 110a-c, and the like.

The power source 101 supplies current to the sections on the system board SB. The ROM 102 stores a memory testing support program and the like used in the present embodiment. Here, the program may be stored in an auxiliary storage device (not illustrated). The program stored in the ROM 102 is loaded into the memory 103a-d (called the “memory 103”, hereafter, if distinction is not needed) or a cache of the CPU 104. Each of the memories 103a-d is, for example, a DIMM (Dual In-line Memory Module), a SIMM (Single In-line Memory Module), or the like, that is to be tested in the present embodiment.

The CPU 104 executes a loaded program. The memory controller 105 executes data exchange control between the CPU 104 and the memory 103 or the ROM 102, or the like. The I/O controller 106 executes input/output control for the PCI slot 107, the LAN card 108, and the like. The graphic board 109 outputs images as signals. The DC-DC converters 110a-c supply currents from the power source 101 to the memory 103, the CPU 104, the graphic board 109, and the like.

On the system board SB, an amperemeter 125 is further connected for measuring a current value supplied to the memory 103. The current value measured by the amperemeter 125 is continuously recorded in a register 121 of the CPU 104.

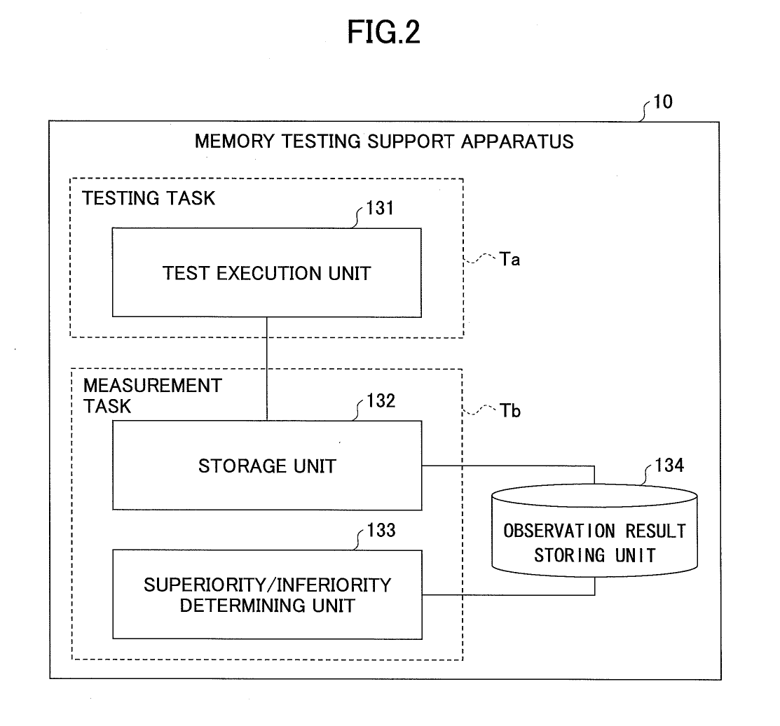

FIG. 2 is a schematic view illustrating a functional configuration example of the memory testing support apparatus 10 according to the present embodiment. In FIG. 2, the memory testing support apparatus 10 includes a test execution unit 131, a storage unit 132, a superiority/inferiority determining unit 133, and the like. These units are implemented by the memory testing support program being loaded into the memory 103 and executed by the CPU 104. The memory testing support apparatus 10 also includes an observation result storing unit 134. The observation result storing unit 134 is implemented, for example, using the register 121, the memory 103, or the like.

The test execution unit 131 executes processing using multiple test patterns (or processing directed by the test pattern) in order (for example, sequentially). A test pattern is a program for executing write and read of the memory 103 based on an access pattern on the memory 103 and a data pattern to be written into the memory 103, to detect a fault in the memory 103. Test patterns have access patterns and data patterns different from each other. Test patterns may be included in the test execution unit 131 (namely, configured as a part of the test execution unit 131), or may not be included in the test execution unit 131. If test patterns are included in the test execution unit 131, the memory testing support program also functions as a memory testing program. If test patterns are not included in the test execution unit 131, the test execution unit 131 starts up a memory testing program that includes a test pattern.

Here, in the present embodiment, the test execution unit 131 operates in one of more tasks (“testing task Ta” in FIG. 2). In the following, processing executed by the testing task Ta may be viewed as processing executed by the test execution unit 131. Also in the present embodiment, execution of processing using a test pattern may be referred to as “execution of a test pattern”.

The storage unit 132 observes the current value measured by the amperemeter 125 during an execution of a test pattern on a constant cycle (namely, periodically), and records an observation result into the observation result storing unit 134 for the test pattern. Here, the storage unit 132 detects switching of a test pattern based on start indication, end indication, etc., of a test pattern issued by the test execution unit 131.

The superiority/inferiority determining unit 133 determines superiority/inferiority of test patterns in terms of effectiveness or aptitude of a test applied to the memory 103 by mutually comparing observation results of the current values for the respective test patterns stored in the observation result storing unit 134. Here, effectiveness or aptitude means likelihood of having high fault detection capability. The superiority/inferiority determining unit 133 also selects a test pattern used for testing the memory 103 based on the determined result of superiority/inferiority.

Namely, the inventors of the present invention noticed that the current value in a memory became great when a fault was detected in the memory in a test performed in the past. Thereupon, the inventors of the present invention considered that likelihood would be high for detecting a fault in a memory if a test pattern is used that induces a greater current value in the memory to be tested. Based on such an idea, the storage unit 132 records an observation result of the current value during an execution of a test pattern, and the superiority/inferiority determining unit 133 determines superiority/inferiority of test patterns based on the observation results.

Here, in the present embodiment, the storage unit 132 and the superiority/inferiority determining unit 133 operate in a task (“measurement task Tb” in FIG. 2).

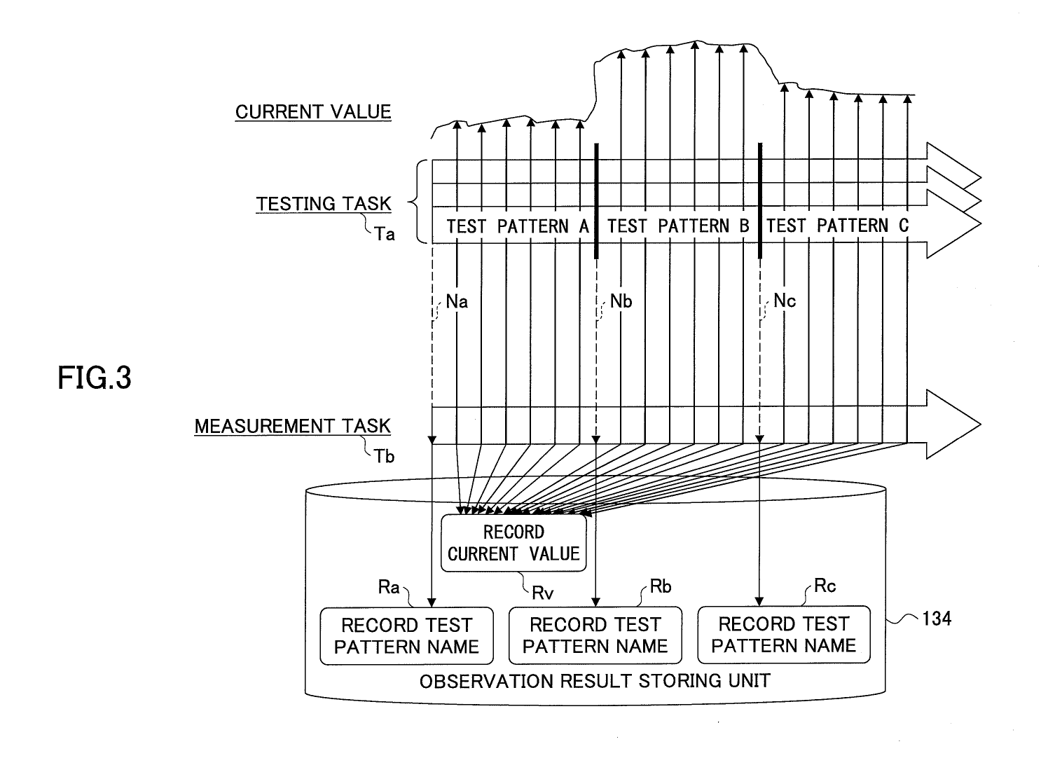

FIG. 3 is a schematic view illustrating a relationship between a testing task and a measurement task. In FIG. 3, an example is illustrated in which the testing task Ta executes test patterns A, B, and C in order. The testing task Ta indicates the start of each of the test patterns to the measurement task Tb (Na, Nb, and Nc). The measurement task Tb records an identification name of a test pattern (called a “test pattern name”, hereafter) specified in a start indication into the observation result storing unit 134 (Ra, Rb, and Rc). Alternatively, a number indicating the order of a test pattern may be used as the test pattern name. In this case, the test pattern name may not be specified in a start indication because it is possible for the measurement task Tb to identify the order of a test pattern by counting the number of occurrences of start indication. After the start indication, the measurement task Tb also observes (or refers to) the current value on a constant cycle that is measured by the amperemeter 125 and recorded in the register 121 record. The measurement task Tb associates an observation result of the current value with the test pattern name of a test pattern under execution, and records it into the observation result storing unit 134 (Rv).

Here, the testing task Ta and the measurement task Tb are executed, for example, by different CPU cores if the CPU 104 is a multi-core processor, or by a single CPU core with task switching if the CPU 104 is a single-core processor. Also, multiple testing tasks Ta may be executed in parallel. Namely, multiple testing tasks Ta may be executed for a single test pattern (for example, test pattern A). In FIG. 3, three white arrows are illustrated for the testing task Ta, which indicates that three testing tasks Ta are executed in parallel. The testing tasks Ta may be executed by different CPU cores or by a single CPU core. If multiple testing tasks Ta are executed, the testing tasks Ta are synchronized with units of test patterns.

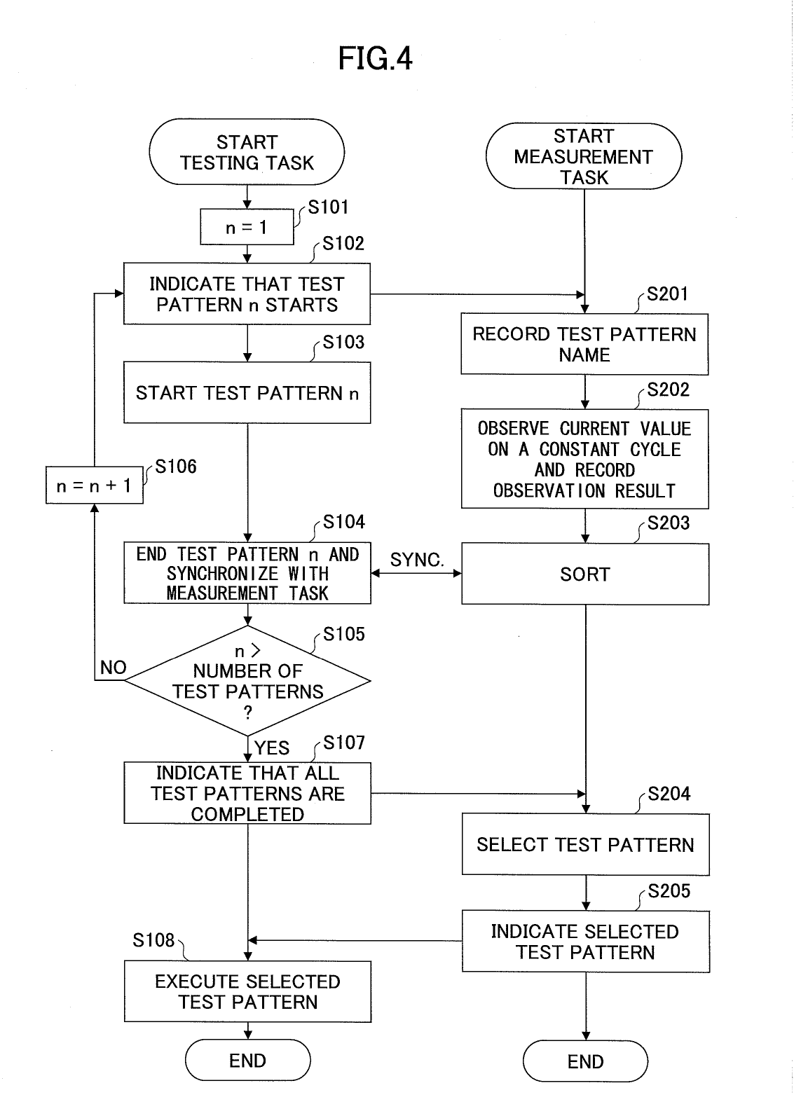

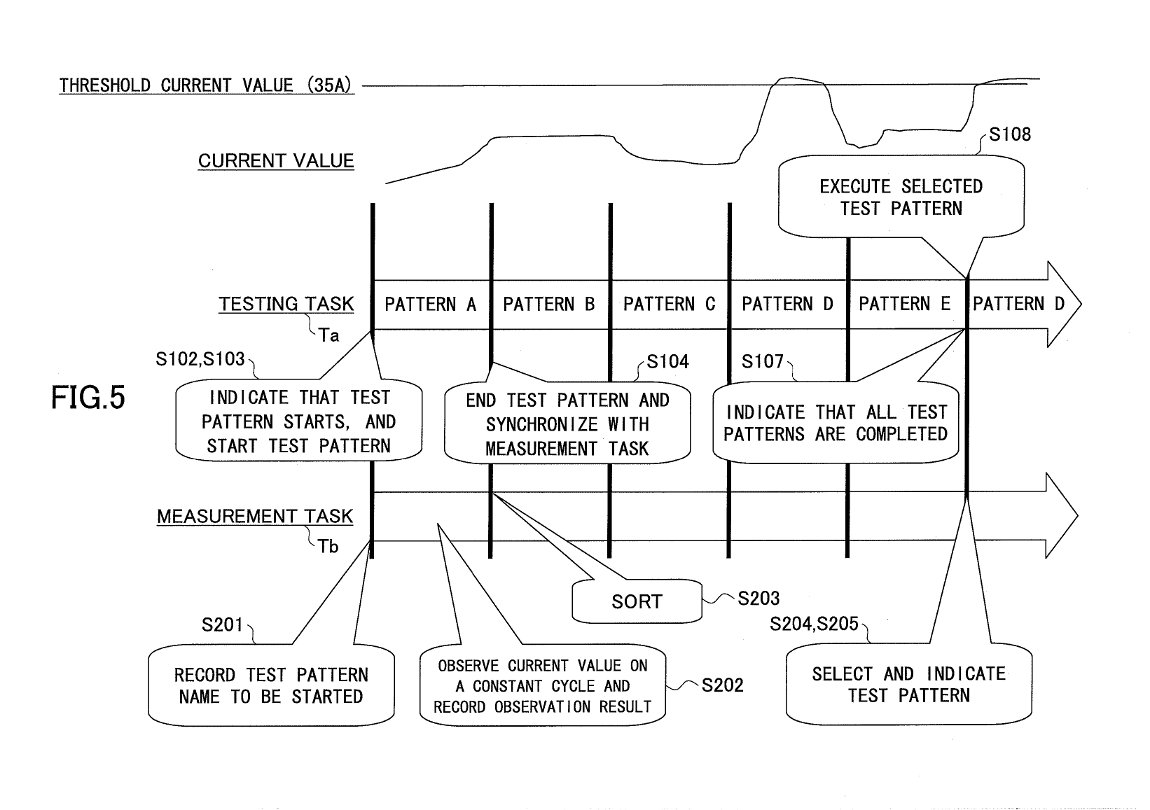

In the following, processing steps of the memory testing support apparatus 10 will be described. FIG. 4 is a flowchart illustrating an example of processing steps in a memory testing support apparatus. Also, FIG. 5 is an example of a timing chart for a testing task and a measurement task. Step numbers in FIG. 5 correspond to Step numbers in FIG. 4.

When started up, the testing task Ta sets one into a variable n (S101). The variable n is a variable for identifying the order of test patterns to be executed. Next, the testing task Ta indicates the start of a test pattern to the measurement task Tb (S102). The indication may be executed, for example, using an interrupt, inter-process communication, or the like. Alternatively, the measurement task Tb may execute polling at a predetermined memory area, at which a value designating start indication of a test pattern is to be record.

Next, the testing task Ta executes the n-th test pattern (test pattern n) (S103). Test pattern n executes data write, read, and the like at addresses in the memory 103. When the test pattern n ends, the testing task Ta synchronizes the processing step with the measurement task Tb (S104). For example, the testing task Ta indicates the end of test pattern n to the measurement task Tb. The testing task Ta also waits for a response to the end indication. The synchronization may be executed using an interrupt, inter-process communication, polling at a memory area, or the like. Synchronization between the testing task Ta and the measurement task Tb described in the following may be done in a similar way.

On the other hand, in response to start indication of a test pattern, the measurement task Tb records the test pattern name of the test pattern into the observation result storing unit 134 (S201).

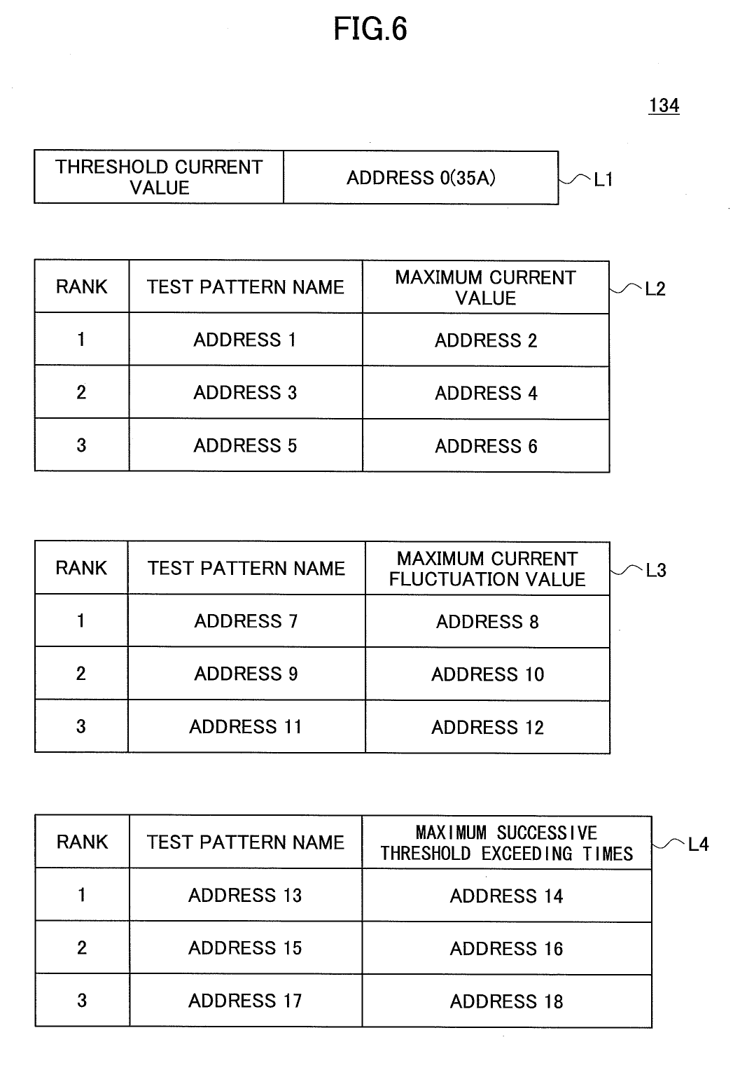

FIG. 6 is a schematic view illustrating a configuration example of the observation result storing unit 134. In the present embodiment, the observation result storing unit 134 includes tables L1, L2 L3, L4 and the like. Here, tables L1-L4 are illustrated in a tabular format for convenience's sake, although items in a table may be distinguished, for example, by the register 121 or addresses in the memory 103 (address 0 to address 18 in FIG. 6). In the present embodiment, the items are distinguished by the addresses.

In table L1, a threshold value for the current value (threshold current value) which is recorded beforehand and is used for counting “successive threshold exceeding times”, will be described later. A preferable value for the threshold current value is below a maximum value of the current flowing in the memory to be tested 103, and yet close to the maximum value. For example, a value obtained having the maximum value multiplied by a coefficient of 0.9 or the like may be set as the threshold current value. The maximum value may be measured by a memory performance evaluation tool, for example, “stream” or the like. In FIG. 6, the threshold current value is set to 35 A as an example.

In table L2, a maximum current value is recorded for each test pattern. The maximum current value represents a maximum current value observed during an execution of a test pattern.

In table L3, a maximum current fluctuation value is recorded for each test pattern. The maximum current fluctuation value represents a maximum difference (fluctuation) between the current value observed during a cycle (current value recorded in the register 125) and a previous observed value. Specifically, the maximum current fluctuation value represents the maximum value of difference between a current value observed at the N-th cycle and a current value observed at the (N+m)-th cycle (m≧1) that are obtained during an execution of a test pattern. Here, as the current value is observed on constant cycles, the difference may represent the magnitude of change of the current value during a predetermined duration. In other words, the magnitude of fluctuation (change) of the current value may be measured in a time unit instead of the unit based on cycles.

In table L4, a value referred to as “successive threshold exceeding times” is recorded for each test pattern. The maximum successive threshold exceeding times represents a maximum number of times in that the current value observed on constant cycles successively exceeds the threshold current value during an execution of a test pattern. For example, if current values observed at the N-th to (N+6)-th cycles exceed the threshold current value for a test pattern, and current values observed at the (N+12)-th to (N+14)-th cycles exceed the threshold current value, the maximum successive threshold exceeding times is seven for the test pattern that have occurred at the N-th to (N+6)-th cycle. Here, where current values are observed on constant cycles, the successive threshold exceeding times may represent a duration in which the current value exceeds the threshold value. In other words, a state in which the current value exceeds the threshold value may be measured in a time unit instead of the unit based on cycles.

At Step S201 described above, the storage unit 132 records the test pattern name of test pattern n into the fields for the test pattern name in the lowest record in table L2, table L3, and table L4, respectively. In the example in FIG. 6, the same test pattern name is recorded at address 5, address 11, and address 17.

Here, in the present embodiment, it is assumed that the number of records in each of tables L2-L4 is predetermined. The number of records may be less than the number of test patterns executed by the testing task Ta. If N high-ranking test patterns need to be extracted from all test patterns that are suitable for the memory to be tested 103, tables L2-L4 may have N+1 records.

Next, the storage unit 132 of the measurement task Tb observes the current value that is measured by the amperemeter 125 and recorded in the register 121 on constant cycles, and records the observation result into the observation result storing unit 134 (S202). Specifically, the maximum current value, the maximum current fluctuation value, and the maximum successive threshold exceeding times are recorded in the lowest records in table L2, table L3, and table L4, respectively. In the example in FIG. 6, the maximum current value, the maximum current fluctuation value, and the maximum successive threshold exceeding times are recorded at address 6, address 12, and address 18.

Here, as an initial maximum current value, the first observed current value is recorded at first. After that, if a current value is observed that is greater than the maximum current value, the maximum current value is updated with the current value. Also, as an initial maximum current fluctuation value, the difference between the first observed current value and the second observed current value is recorded at first. After that, if the difference between the N-th observed value and the (N+m)-th observed value (m≧1) exceeds the maximum current fluctuation value at the moment, the maximum current fluctuation value is updated with the difference. Also, as initial maximum successive threshold exceeding times, one (numerical value) is recorded if a current value is observed that exceeds the threshold current value for the first time. After the first observation, if the next observed value also exceeds the threshold current value, one is added to the maximum successive threshold exceeding times, and it goes on at every successive observation. After that, if the observed value becomes less than the threshold current value, then again, the observed value exceeds the threshold current value, one is recorded in the register 121 or in the memory 103 at an address other than address 18 (for example, address 19 (not illustrated)). After the observation, if the observed value exceeds the threshold current value, one is added at address 19 at every successive observation. After that, when the observed value becomes less than the threshold current value, if the value at address 19 is greater than the maximum successive threshold exceeding times at the moment, the maximum successive threshold exceeding times is updated with the value recorded at address 19.

The steps described above are continuously executed during an execution of a test pattern.

Next, the superiority/inferiority determining unit 133 of the measurement task Tb sorts records of the observation results in descending order on each of table 2, table 3, and table 4 when the end of test pattern n is indicated by the testing task Ta (S203). Namely, superiority/inferiority of the observation results is determined. Here, an observation result includes a maximum current value, a maximum current fluctuation value, and maximum successive threshold exceeding times. Therefore, when Step S203 is executed for the first test pattern, the test pattern names at address 5, address 11, and address 17 are just copied into address 1, address 7, and address 13, respectively, in FIG. 6. Also, the values at address 6, address 12, and address 18 are copied into address 2, address 8, and address 14, respectively. Here, in FIG. 6, the ranks in tables L2-L4 represent sorted results, respectively.

Having completed the sort, the superiority/inferiority determining unit 133 makes a reply for the end indication of test pattern to the testing task Ta. In response to the reply, the testing task Ta executes Steps S102-S104 for the next test pattern (S105—NO and S106). On the other hand, the measurement task Tb executes Steps S201-S203 for the next test pattern. These steps are repeated until executions of all test patterns are completed (S105). Here, the test pattern name and the observation result of a test pattern are recorded in the lowest records in tables L2-L4 of the observation result storing unit 134 for the moment (at Steps S201-S202 for the test pattern). Namely, the lowest records in tables L2-L4 of the observation result storing unit 134 are overwritten with every test pattern. After that, if the observation result of the test pattern happens to be greater than any one of the high-ranking records, the content of the lowest record may be exchanged with the content of the high-ranking record by sorting at Step S203.

Consequently, if the number of records in each of tables L2-L4 is N, up to the (N−1)-th high-ranking observation results among all test patterns are recorded in the records except for the lowest-rank record. Here, the sorted results may differ among tables L2-L4.

Here, if the register 121 or the memory 103 of the observation result storing unit 134 has sufficient capacity for recording the observation results for all test patterns, the observation results may not be sorted at every execution of a test pattern. For example, the observation results of test patterns may be recorded in order from the uppermost records in the respective tables, which are sorted in the respective tables after all test patterns have been completed.

When all test patterns have been completed (S105—Yes), the testing task Ta indicates the end of executions of all test patterns to the measurement task Tb (S107).

In response to the indication, the superiority/inferiority determining unit 133 of the measurement task Tb automatically selects a test pattern used for a test of the memory 103 based on table L2, table L3, and table L4 of the observation result storing unit 134 (S204). For example, the superiority/inferiority determining unit 133 obtains test pattern names recorded in the uppermost or up to the m-th high-ranking records from table L2, table L3, and table L4, respectively. Namely, among all of the test patterns, test pattern names are obtained that correspond to the maximum or up to the m-th high-ranking current values, the maximum or up to the m-th high-ranking current fluctuation values, and the maximum or up to the m-th high-ranking successive threshold exceeding times. Here, the test pattern names obtained from tables L2-L4 may not be the same. This is because the sorted results may differ among tables L2-L4. Therefore, test patterns may not necessarily be selected uniquely.

Next, the superiority/inferiority determining unit 133 indicates the obtained test pattern names to the testing task Ta (S205). In response to the indication, the testing task Ta executes the test pattern corresponding to one of the indicated test pattern names for a predetermined time (for example, two hour or the like) (S108). If there are multiple corresponding test patterns, the test patterns may be executed in an arbitrary order.

In FIG. 5, an example is illustrated in which test pattern D is executed as the selected test pattern that has the maximum current value, the maximum current fluctuation value, and the maximum successive threshold exceeding times among test patterns A-E, as can be seen from the curve of the current value.

However, the selected test may not be executed automatically, but the selected test pattern name may be output in a way that a user can recognize it (for example, displaying, printing, sending via a network, or the like).

Here, a test pattern may be selected by a majority vote if the number of test patterns to be executed needs to be limited within a predetermined number (for example, one) and the number of test patterns selected at Step S204 exceeds the predetermined number. Namely, if two test pattern names are equivalent among three test pattern names obtained from the three tables, the test pattern name may be selected as the test pattern.

Also, a user may prioritize selection criteria if the user has a desirable test to be executed. Namely, if a test is required to focus on instantaneous heavy load on the memory 103, the test pattern with the maximum current value may be selected. Also, if a test is required to focus on load change on the memory 103, the test pattern with the maximum current fluctuation value may be selected. Also, if a test is required to focus on continuous heavy load on the memory 103, the test pattern with the maximum successive threshold exceeding times may be selected.

Such priority given by a user may be recorded in advance as setting information in the ROM 102, the auxiliary storage device (not illustrated), or the like, or taken interactively from a user as input on a displayed GUI (Graphical User Interface).

Also, a test pattern may not be selected automatically. For example, a user can determine superiority/inferiority of the test patterns by referring to contents recorded in tables L2-L4 of the observation result storing unit 134. In other words, by recording in tables L2-L4 of the observation result storing unit 134, it is possible to provide an effective basis for determination by a user when selecting the test pattern. Consequently, a test pattern can be selected efficiently. To make it easy for a user to refer to contents recorded in tables L2-L4 of the observation result storing unit 134, for example, the superiority/inferiority determining unit 133 may output the contents in a format easy to grasp for a user.

As described above, according to the present embodiment, a test pattern for detecting a fault in a memory to be tested 103 can be selected efficiently. Namely, it is possible to select a test pattern suitable for the memory to be tested 103 without continuously executing test patterns until a fault is detected as done conventionally. Consequently, labor-hours can be reduced for memory testing in total.

It is also possible to reduce workload of memory testing because a selected test pattern is automatically executed.

Also, a test pattern can be selected in accordance with a user's need by making a preferred parameter selectable among a maximum current value, a maximum current fluctuation value, maximum successive threshold exceeding times, or the like,

Here, by recording an additional parameter other than a maximum current value, a maximum current fluctuation value, and maximum successive threshold exceeding times, superiority/inferiority of test patterns may be determined based on the additional parameter. For example, a maximum value of the total number of times that the observed current value exceeds the threshold current value may be recorded for each test pattern. Also, the difference between a minimum current value and a maximum current value may be recorded for each test pattern. Also, the average value of the current value may be calculated and recorded for each test pattern. Also, a time during which the observed current value exceeds the threshold current value may be recorded. Also, the ratio of the above time to a test pattern execution time may be calculated and recorded.

Further, observation results may be recorded for partitioned units within a test pattern. Superiority/inferiority may be determined for the units. In other words, units of test patterns may be determined discretionarily according to the present embodiment.

All examples and conditional language recited herein are intended for pedagogical purposes to aid the reader in understanding the invention and the concepts contributed by the inventor to furthering the art, and are to be construed as being without limitation to such specifically recited r examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A memory testing support method comprising:
executing a procedure using a plurality of test patterns on a memory to be tested;
recording an observation result of a current value flowing in the memory during the execution of the procedure using each of the test patterns into a storing section; and
determining superiority or inferiority of the test patterns in terms of effectiveness of testing the memory based on the observation results of the test patterns recorded in the storing section.

2. The memory testing support method as claimed in claim 1, further comprising:
selecting one of the test patterns to be used for the testing of the memory based on the determination result of superiority or inferiority; and
executing the procedure using the selected test pattern.

3. The memory testing support method as claimed in claim 1, wherein the determining determines superiority or inferiority based on a maximum value of the current value obtained for each of the test patterns.

4. The memory testing support method as claimed in claim 1, wherein the determining determines superiority or inferiority based on magnitude of change of the current value within a predetermined time, obtained for each of the test patterns.

5. The memory testing support method as claimed in claim 1, wherein the determining determines superiority or inferiority based on a duration during which the current value exceeds a predetermined threshold value, obtained for each of the test patterns.

6. A memory testing support apparatus comprising:
an execution unit configured to execute a procedure using a plurality of test patterns on a memory to be tested;
a storage unit configured to record an observation result of a current value flowing in the memory during an execution of the procedure using each of the test patterns into a storing section; and
a determining unit configured to determine superiority or inferiority of the test patterns in terms of effectiveness of testing the memory based on the observation results of the test patterns recorded in the storing section.
